(19) United States
(12) Patent Application Publication
(10) Pub. No.: US 2006/0238454 A1
(43) Pub. Date: Oct. 26, 2006

(54) ANALOG FRONT-END CIRCUIT FOR DIGITAL DISPLAYING APPARATUS AND CONTROL METHOD THEREOF

(76) Inventors: Chi-Feng Wang, Taipei Hsien (TW); Jui-Yuan Tsai, Tai-Nan City (TW); Ming-Yuh Yeh, Taipei City (TW)

Correspondence Address: NORTH AMERICA INTELLECTUAL PROPERTY CORPORATION, P.O. BOX 506, MERRIFIELD, VA, 22116, US

(21) Appl. No.: 11/428,403

(22) Filed: Jul. 2, 2006

Related U.S. Application Data
(63) Continuation-in-part of application No. 10/771,031, filed on Feb. 3, 2004.
(63) Continuation-in-part of application No. 11/279,251, filed on Apr. 11, 2006.

(30) Foreign Application Priority Data
Apr. 17, 2003 (TW) 092108991
Apr. 11, 2005 (TW) 094111364

(51) Int. Cl. G09G 3/28; H03M 1/12

(52) U.S. Cl. 345/72; 341/155

(57) ABSTRACT

An analog front-end (AFE) circuit of a digital display is disclosed including: a first analog-to-digital converter (ADC) for converting a first analog video signal into a first digital video signal according to a first sampling signal; a second ADC for converting the first analog video signal into a second digital video signal according to the first sampling signal; a first multiplexer for selectively outputting the first digital video signal or the second digital video signal according to a first output order; and a first clock control circuit for randomly adjusting the first output order of the first and the second digital video signals.

### CROSS REFERENCE TO RELATED APPLICATIONS

This is a continuation-in-part of U.S. application Ser. No. 10/771,031, filed Feb. 3, 2004, entitled “IMAGE SIGNAL PROCESSING METHOD AND DEVICE,” and U.S. application Ser. No. 11/279,251, filed Apr. 11, 2006, entitled “ANALOG FRONT-END CIRCUIT FOR DIGITAL DISPLAYING APPARATUS AND CONTROL METHOD THEREOF,” which are cooperated by reference herein.

### BACKGROUND OF THE INVENTION

1. Field of the Invention

The present invention relates to analog front-end (AFE) circuits, and more particularly, to analog front-end circuits for digital displaying apparatus and control methods thereof.

2. Description of the Prior Art

In various digital displaying apparatuses, such as the liquid crystal display (LCD) and the plasma display panel (PDP), an analog front-end (AFE) circuit is typically employed to convert the analog RGB signals into digital signals.

Please refer to FIG. 1, which shows a block diagram of a conventional analog front-end (AFE) circuit 100 of a digital display. As shown, the AFE circuit 100 comprises a clock generator 110, a bandgap voltage reference 120, and three color processing modules 130, 140, and 150 for processing the three analog signals R, G, and B, respectively. Each color-processing module comprises a clamp circuit, a gain and offset adjusting circuit, and an analog-to-digital converter (ADC). The operations of the above components are well known in the art and further details are therefore omitted for brevity.

The performance of the analog-to-digital converters of the AFE circuit 100 influences the image quality of the digital display. For example, in a 15-inch LCD monitor, the ADC must operate at 94.5 MHz when the displaying mode is configured to 1024*768*85 Hz (i.e., the XGA mode). In a 17-inch LCD monitor, the ADC must operate at 157.5 MHz when the displaying mode is configured to 1280*1024*85 Hz (i.e., the SXGA mode). Thus, it can be seen that the ADC must operate at higher speeds for higher resolution displaying modes.

In the conventional art, a time-interleaved ADC architecture is typically employed in the AFE circuit. FIG. 2 illustrates a simplified block diagram of an AFE circuit 200 adopting the interleaved ADC architecture according to the prior art. In the AFE circuit 200, however, the mismatch between analog-to-digital converters 220 and 230 easily results in problems such as: offset error, gain error, and phase difference. In some displaying modes or pictures, these problems become more obvious and may be detectable by human eyes. For example, an offset between the ADCs 220 and 230 may cause the presence of stripes or saw tooth artifacts in the screen image thereby negatively affecting the image quality of the digital display.

### SUMMARY OF THE INVENTION

It is therefore an objective of the claimed invention to provide analog front-end circuits of a digital display to solve the above-mentioned problems.

An exemplary embodiment of an analog front-end (AFE) circuit of a digital display is disclosed comprising: a first analog-to-digital converter (ADC) for converting a first analog video signal into a first digital video signal according to a first sampling signal; a second ADC for converting the first analog video signal into a second digital video signal according to the first sampling signal; a first multiplexer for selectively outputting the first digital video signal or the second digital video signal according to a first output order; and a first clock control circuit for randomly adjusting the first output order of the first and the second digital video signals.

An exemplary embodiment of a method for controlling an analog front-end circuit of a digital display is disclosed comprising: generating a first sampling signal according to a working clock; converting a first analog video signal into a first digital video signal according to the first sampling signal; converting the first analog video signal into a second digital video signal according to the first sampling signal; randomly adjusting a first output order of the first digital video signal and the second digital video signal; and outputting the first digital video signal and the second digital video signal according to the first output order.

An exemplary embodiment of an analog front-end (AFE) circuit of a digital display is disclosed comprising: a first analog-to-digital converter (ADC) for converting an analog video signal into a first digital video signal according to a sampling signal; a second ADC for converting the analog video signal into a second digital video signal according to the sampling signal; a random generator for generating a random signal; a control signal generator, coupled to the random generator and the multiplexer, for generating a first bit pair and a second bit pair according to the random signal; and a multiplexer coupled to the control signal generator for selectively outputting the first digital video signal or the second digital video signal under the control of the output bit pair of the control signal generator; wherein the second bit pair is opposite to the first bit pair.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a block diagram of an analog front-end (AFE) circuit of a digital display according to the prior art.

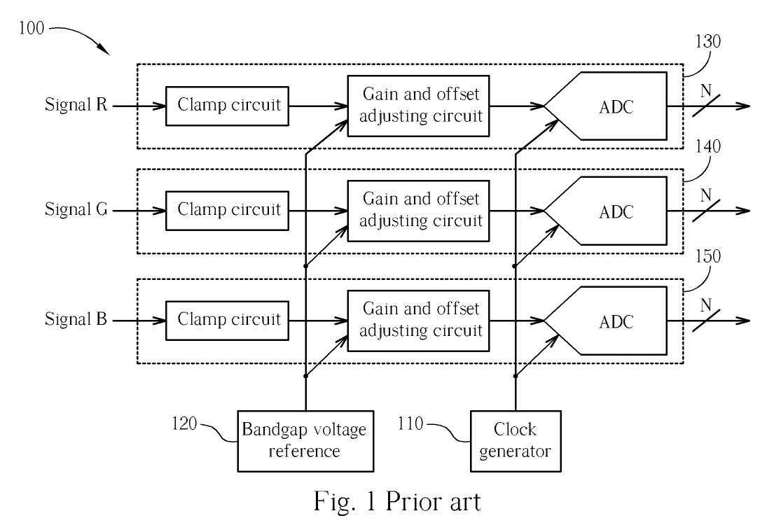

FIG. 2 is a simplified block diagram of an AFE circuit with interleaved analog-to-digital converters according to the prior art.

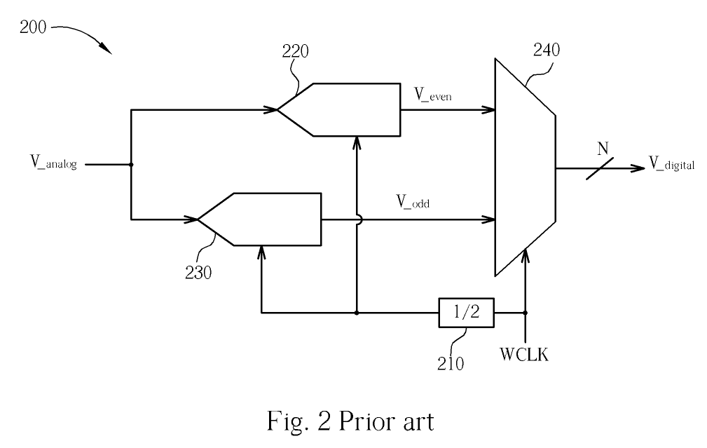

FIG. 3 is a simplified block diagram of an AFE circuit according to one embodiment of the present invention.

FIG. 4 is a block diagram of a control unit of FIG. 3 according to a first embodiment of the present invention.

FIG. 5 is a block diagram of the control unit of FIG. 3 according to a second embodiment of the present invention.

FIG. 6 is a simplified block diagram of an AFE circuit adopting the interleaved ADC architecture according to another embodiment of the present invention.

FIG. 7 is a block diagram of a random generator of FIG. 6 according to an exemplary embodiment.

FIG. 8 is a simplified block diagram of an AFE circuit according to another embodiment of the present invention.

### DETAILED DESCRIPTION

The operations for processing each of the RGB signals are substantially the same as one other. For convenience and simplification of the descriptions, the operations of processing a single RGB signals is utilized as an example hereinafter.

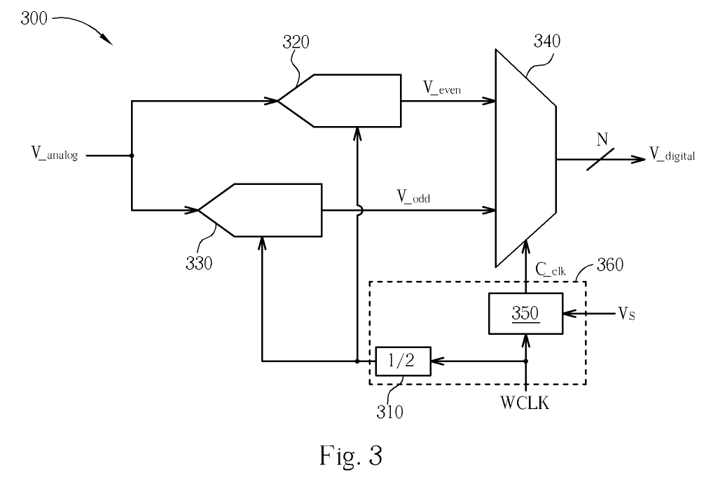

Please refer to FIG. 3, which shows a simplified block diagram of an AFE circuit 300 according to one embodiment of the present invention. The AFE circuit 300 adopts the interleaved ADC architecture. As shown, the AFE circuit 300 comprises a first analog-to-digital converter (ADC) 320, a second ADC 330, and a clock control circuit 360; wherein the first and second ADCs construct a time-interleaved ADC. In FIG. 3, the analog video signal V_analog corresponds to one of the three primary colors R, G, or B.

The clock control circuit 360 is arranged for intermittently or alternately inverting a working clock to generate a control signal. The clock control circuit 360 is also employed to generate a sampling signal according to the control signal or the working clock. In one embodiment, the clock control circuit 360 comprises a first frequency divider 310 and a control unit 350. In this embodiment, the first frequency divider 310 is arranged for dividing the frequency of a working clock WCLK by two to generate the sampling signal. In other words, the frequency of the sampling signal is half of the working clock WCLK. The first ADC 320 converts the even pixels of the analog video signal V_analog into a first digital video signal V_even according to the sampling signal. The second ADC 330 converts the odd pixels of the analog video signal V_analog into a second digital video signal V_odd according to the sampling signal.

In practice, the first frequency divider 310 of the clock control circuit 360 can be designed to generate the sampling signal by dividing the frequency of the control signal or an inverted signal of the working clock WCLK.

In this embodiment, the control unit 350 of the clock control circuit 360 is arranged for intermittently inverting the working clock WCLK to generate a control signal C_clk. The control signal C_clk is employed to control a first multiplexer 340 to selectively output the first digital video signal V_even or the second digital video signal V_odd.

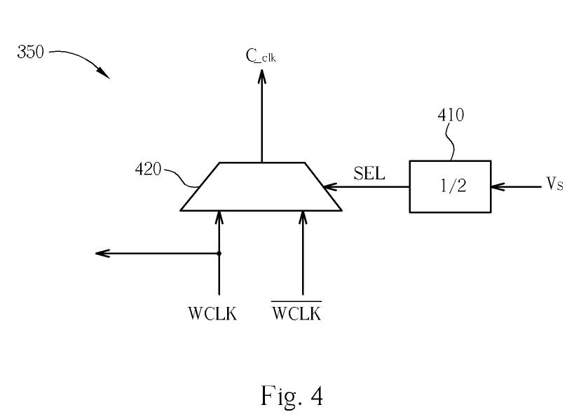

In practice, the control unit 350 can be implemented utilizing other design choices. For example, FIG. 4 shows a block diagram of the control unit 350 according to a first embodiment of the present invention. In this embodiment, a second frequency divider 410 is employed in the control unit 350 to divide the frequency of a vertical sync signal Vs by two to produce a selection signal SEL. A second multiplexer 420 is then utilized to selectively output the working clock WCLK or an inverted clock \overline{WCLK} of the working clock WCLK to be the control signal C_clk under the control of the selection signal SEL.

As is well known in the art, each pulse of the vertical sync signal Vs corresponds to an individual frame. In another aspect, the interval between two successive pulses corresponds to the data length of an entire frame. Accordingly, the logical level of the selection signal SEL generated from the second frequency divider 410 will be alternated between two successive frames. For example, in one embodiment, the selection signal SEL is at logic 1 during the period of each odd frame and then goes to logic 0 during the period of each even frame. If the second multiplexer 420 outputs the working clock WCLK as the control signal C_clk when the selection signal SEL is at logic 1 (i.e., during the period of each odd frame), then it will output the inverted clock \overline{WCLK} as the control signal C_clk when the selection signal SEL goes to logic 0 (i.e., during the period of each even frame).

Therefore, the timing of outputting the first digital video signal V_even and the second digital video signal V_odd from the first multiplexer 340 during the period of the odd frame is opposite to that during the period of the even frame. As a result, the light stripes and shade stripes on the odd picture caused by the mismatch between the ADC 320 and ADC 330 will be swapped or alternated on the even frame. Specifically, the light stripes on the odd frame will become shade stripes on the even frame and the shade stripes on the odd frame will become light stripes on the even frame. The human eye averages the visual effects of successive frames. Therefore, the human eye will not be able to detect the above-described image defects caused by the mismatch between ADC 320 and ADC 330.

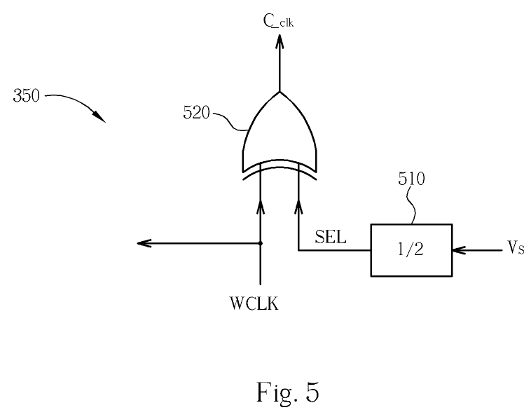

FIG. 5 shows a block diagram of the control unit 350 according to a second embodiment of the present invention. In this embodiment, a third frequency divider 510 is employed in the control unit 350 to divide the frequency of the vertical sync signal Vs by two to generate a selection signal SEL. Then, an XOR gate 520 is utilized for receiving the selection signal SEL and the working clock WCLK to produce the control signal C_clk. By utilizing the XOR gate 520, the polarity of the control signal C_clk will alternate between two successive frames, i.e. the polarity of the control signal C_clk during the period of the odd frame will be opposite to the polarity of the control signal C_clk during the period of the even frame. This renders the timing of outputting the first digital video signal V_even and the second digital video signal V_odd from the first multiplexer 340 during the period of the odd frame as opposite of that during the period of the even frame.

In practice, the divisor of the frequency dividers 410 and 510 can be set to another value other than 2. For example, the divisor of the frequency dividers 410 and 510 can be set to 4. When a divisor is set to a value of 4 the timing of outputting the first digital video signal V_even and the second digital video signal V_odd from the first multiplexer 340 changes every other frame.

In addition, the clock control circuit 360 can be designed to invert the working clock WCLK every other predetermined time period. Thereto, in another embodiment, the frequency divider 410 or 510 of the clock control circuit 360 is replaced with a counter (not shown). The counter is utilized for generating a count value by counting pulses of the working clock WCLK or by counting pulses of the vertical sync signal Vs. In this embodiment, each time the count value reaches a predetermined value; the clock control circuit 360 utilizes the second multiplexer 420 or the XOR gate 520, mentioned above, to invert the working clock WCLK.

Note that, other means exist that allows the first multiplexer 340 to periodically swap the output timing of the digital video signals V_even and V_odd. These other means should also be included in the embodiment of the present invention.

Additionally, in the AFE circuit 300, the number of ADCs employed to process each color signal can be extended beyond two. In this situation, the divisor of the first frequency divider 310 should be correspondingly adjusted according to the number of ADCs employed. For example, when three ADCs are employed to process a single color signal, the divisor of the first frequency divider 310 should be configured to three. In practical implementations, since the control signal C_clk generated from the control unit 350 has the same frequency as the working clock WCLK, the first frequency divider 310 can also divide the frequency of the control signal C_clk to generate the sampling signal.

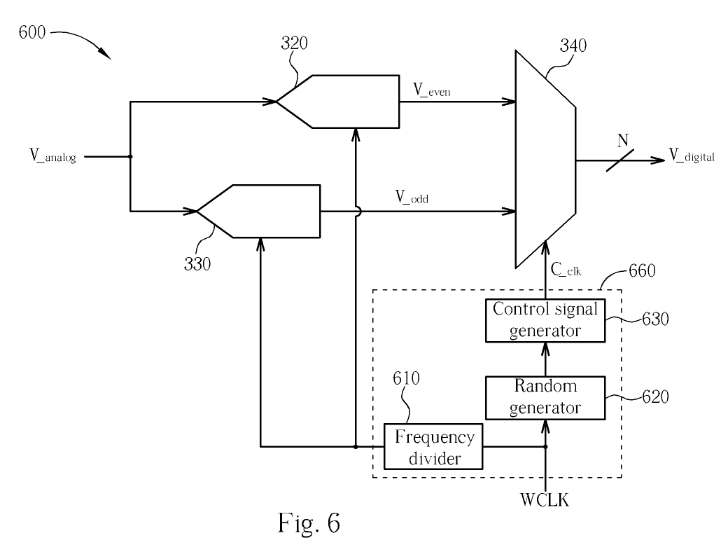

Please refer to FIG. 6, which shows a simplified block diagram of an AFE circuit 600 adopting the interleaved ADC architecture according to another embodiment of the present invention. A difference between the AFE circuit 600 and the AFE circuit 300 is that a clock control circuit 660 of the AFE circuit 600 is implemented differing from the clock control circuit 360 of the AFE circuit 300. In this embodiment, the clock control circuit 660 is arranged for generating a sampling signal according to a working clock WCLK, and for randomly adjusting the output order (i.e., output timing) of the first multiplexer 340. Hereinafter, the operations and implementations of the clock control circuit 660 are described in more detail.

In a preferred embodiment, the clock control circuit 660 comprises a frequency divider 610, a random generator 620, and a control signal generator 630 as shown in FIG. 6. The frequency divider 610 is arranged for dividing the frequency of the working clock WCLK by a predetermined divisor (e.g., two) to generate the sampling signal required by the first ADC 320 and the second ADC 330. The random generator 620 is arranged for randomly generating a zero or a one to the control signal generator 630 during each clock period of the working clock WCLK. Then, the control signal generator 630 generates a control signal C_clk according to the value generated by the random generator 620 to control the output order of the first multiplexer 340. In this embodiment, the control signal generator 630 outputs a bit pair “01” to the first multiplexer 340 when receives a zero from the random generator 610, and outputs an opposite bit pair “10” to the first multiplexer 340 when receives a one from the random generator 620. As a result, the control signal C_clk generated by the control signal generator 630 is a random combination of the bit pair “01” and the opposite bit pair “10” due to the output value of the random generator 620 is generated randomly.

As in the foregoing descriptions, the output order of the multiplexer 340 is determined by the control signal C_clk. Specifically, the multiplexer 340 outputs the first digital video signal V_even and the second digital video signal V_odd in a predetermined order when receives the bit pair “01”, and outputs the first digital video signal V_even and the second digital video signal V_odd in an opposite order when receives the opposite bit pair “10”. In such a scheme, the output order for each pixel pair of a frame of another embodiment may be opposite to that for next pixel pair of the frame.

In another embodiment, the control signal generator 630 records an output bit sequence corresponding to a current scan line of a frame and generates an opposite bit sequence for a next scan line of the frame. For example, if the bit sequence, corresponding to the current scan line, generated by the control signal generator 630 is 101001 . . . 0110, the control signal generator 630 can simply output an opposite bit sequence 010110 . . . 1001 as the control signal C_clk of the first multiplexer 340 for the next scan line.

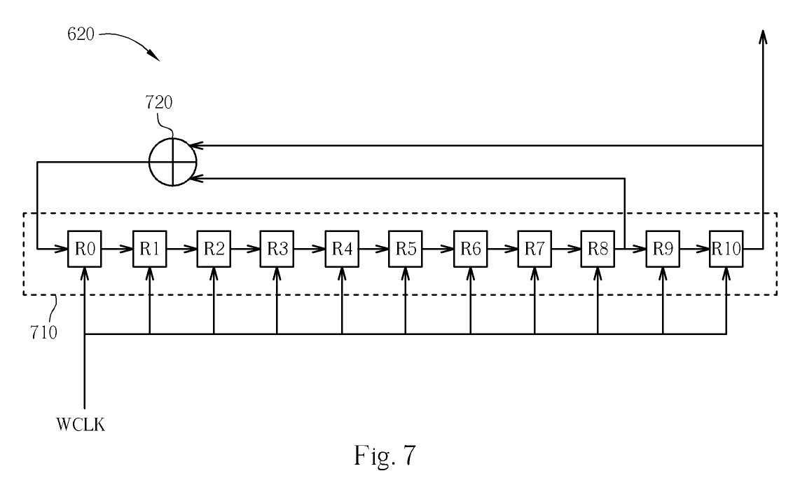

In practice, the random generator 620 can be implemented with various hardware means, software means, or hybrid of hardware and software means. For example, FIG. 7 is a block diagram of the random generator 620 according to an exemplary embodiment. In this embodiment, the random generator 620 is realized by a pseudo-random generator, which is formed by a shift register 710 and an XOR gate 720. As illustrated, the shift register 710 is formed by eleven register units R0, R1, . . . , and R10, and the XOR gate 720 generates an output value as the input value of the shift register 710 according to the outputs of the register units R8 and R10. In operations, the shift register 710 is loaded with a set of initial values that may be any combination of ones and zeros with the exception that they cannot all be zero. As a result, the last register unit R10 of the shift register 710 outputs a pseudo-random sequence according to the working clock WCLK to the control signal generator 630.

Please note that the architecture of the pseudo-random generator shown in FIG. 7 is merely an example of the random generator 620 rather than a restriction of the practical implementations. For example, the shift register 710 may be implemented with less or more register units. In addition, the two inputs of the XOR gate 720 may be coupled to other register units instead of that illustrated in the previous embodiment.

As described previously, the operations for processing each of the RGB signals are substantially the same as one other. Accordingly, the three color processing modules of the AFE circuit illustrated above typically operate under the control of the same clock control circuit (such as 360 or 660), but this is not a restriction of the present invention.

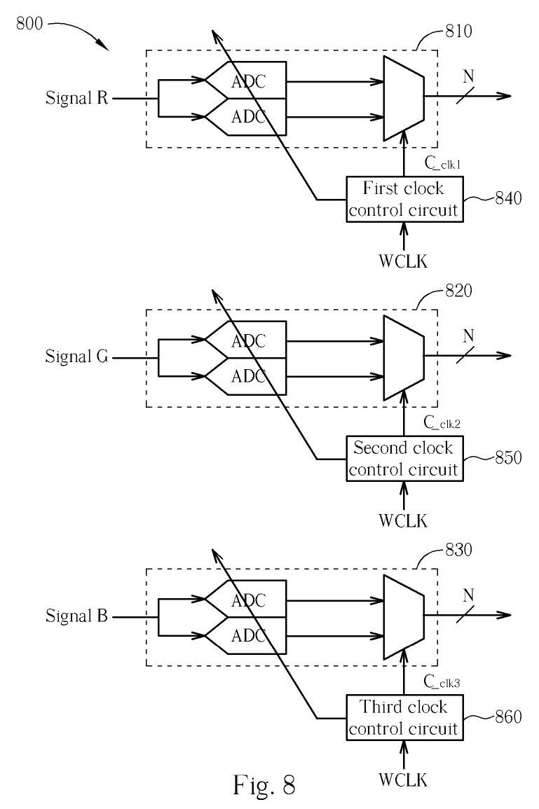

By way of example, FIG. 8, shows a simplified block diagram of an AFE circuit 800 according to another embodiment of the present invention. The AFE circuit 800 comprises three color processing modules 810, 820, and 830, and three clock control circuits 840, 850, and 860. The three color processing modules 810, 820, and 830 are arranged for processing the three analog signals R, G, and B, respectively. The operations of each of the color processing modules 810, 820, and 830 are substantially the same as that illustrated in the previous embodiments, and repeated descriptions are therefore omitted herein for the sake of brevity.

In the AFE circuit 800, the three clock control circuits 840, 850, and 860 are arranged for controlling the three color processing modules 810, 820, and 830, respectively. In a preferred embodiment, the operations and implementations of each clock control circuit of the AFE circuit 800 are substantially the same as the clock control circuit 660 described previously. Accordingly, further details are omitted herein for the sake of brevity. In operations, the three clock control circuits 840, 850, and 860 of the AFE circuit 800 operate independently. Specifically, the generation of the three control signals C_clk1, C_clk2, and C_clk3 are independent to each other, so the three control signals C_clk1, C_clk2, and C_clk3 may differ from each other. As a result, the output timings of the three multiplexer of the three color processing modules 810, 820, and 830 are irrelative.

In practice, some of the three clock control circuits 840, 850, and 860 can be implemented as well as the clock control circuit 360 in the embodiment shown in FIG. 3. In other words, the disclosed clock control circuits 360 and 660 can be concurrently employed in the AFE circuit of the present invention.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An analog front-end (AFE) circuit of a digital display, comprising:
a first analog-to-digital converter (ADC) for converting a first analog video signal into a first digital video signal according to a first sampling signal;
a second ADC for converting the first analog video signal into a second digital video signal according to the first sampling signal;
a first multiplexer for selectively outputting the first digital video signal or the second digital video signal according to a first output order; and
a first clock control circuit for randomly adjusting the first output order of the first and the second digital video signals.

2. The circuit of claim 1, wherein the first analog video signal corresponds to one of the three primary colors R, G, or B.

3. The circuit of claim 1, wherein the first digital video signal corresponds to even pixels while the second digital video signal corresponds to odd pixels.

4. The circuit of claim 1, wherein the first clock control circuit comprises:
a frequency divider for dividing the frequency of the working clock to generate the first sampling signal.

5. The circuit of claim 1, wherein the first clock control circuit comprises:
a random generator for randomly generating a zero or a one according to the working clock; and
a control signal generator for generating a first control signal according to the value generated by the random generator to control the output timing of the first multiplexer.

6. The circuit of claim 5, wherein the first control signal is a first bit pair when the random generator outputs a zero, and the first control signal is a second bit pair when the random generator outputs a one.

7. The circuit of claim 6, wherein the two bits of the first bit pair are not the same.

8. The circuit of claim 5, wherein the random generator is a pseudo random generator.

9. The circuit of claim 8, wherein the pseudo random generator comprises:
a shift register comprising a plurality of register units; and
a logic gate for generating a value as the input value of the shift register according to outputs of two of the plurality of register units.

10. The circuit of claim 1, further comprising:
a third ADC for converting a second analog video signal into a third digital video signal according to a second sampling signal;
a fourth ADC for converting the second analog video signal into a fourth digital video signal according to the second sampling signal;
a second multiplexer for selectively outputting the third digital video signal or the fourth digital video signal according a second output order; and
a second clock control circuit for randomly adjusting the second output order of the third and the fourth digital video signal.

11. The circuit of claim 1, further comprising:
a third ADC coupled to the second clock control circuit for converting a second analog video signal into a third digital video signal according to a second sampling signal;
a fourth ADC coupled to the second clock control circuit for converting the second analog video signal into a fourth digital video signal according to the second sampling signal; and
a second multiplexer for selectively outputting the third digital video signal or the fourth digital video signal according to the first output order.

12. A method for controlling an analog front-end circuit of a digital display, comprising:
generating a first sampling signal according to a working clock;
converting a first analog video signal into a first digital video signal according to the first sampling signal;
converting the first analog video signal into a second digital video signal according to the first sampling signal;
randomly adjusting a first output order of the first digital video signal and the second digital video signal; and
outputting the first digital video signal and the second digital video signal according to the first output order.

13. The method of claim 12, wherein the first analog video signal corresponds to one of the three primary colors R, G, or B.

14. The method of claim 12, wherein the first digital video signal corresponds to even pixels while the second digital video signal corresponds to odd pixels.

15. The method of claim 12, wherein the step of generating the first sampling signal comprises:
dividing the frequency of the working clock to generate the first sampling signal.

16. The method of claim 12, wherein the randomly adjusting step comprises:
generating a random signal; and
generating the first output order according to the random signal.

17. The method of claim 16, wherein
when the value of the random signal is a zero, the first digital video signal and the second digital video signal are output in a predetermined order; and
when the value of the random signal is a one, the first digital video signal and the second digital video signal are output in an opposite order.

18. The method of claim 12, further comprising:
generating a second sampling signal according to the working clock;
converting a second analog video signal into a third digital video signal according to the second sampling signal;
converting the second analog video signal into a fourth digital video signal according to the second sampling signal;
randomly adjusting a second output order of the third and the fourth digital video signals; and
outputting the third digital video signal and the fourth digital video signal according to the second output order.

19. The method of claim 12, further comprising:
generating a second sampling signal according to the working clock;
converting a second analog video signal into a third digital video signal according to the second sampling signal;
converting the second analog video signal into a fourth digital video signal according to the second sampling signal; and
outputting the third digital video signal and the fourth digital video signal according to the first output order.

20. An analog front-end (AFE) circuit of a digital display, comprising:
a first analog-to-digital converter (ADC) for converting an analog video signal into a first digital video signal according to a sampling signal;
a second ADC for converting the analog video signal into a second digital video signal according to the sampling signal;
a random generator for generating a random signal;
a control signal generator, coupled to the random generator and the multiplexer, for generating a first bit pair and a second bit pair according to the random signal; and
a multiplexer coupled to the control signal generator for selectively outputting the first digital video signal or the second digital video signal under the control of the output bit pair of the control signal generator;
wherein the second bit pair is opposite to the first bit pair.
